(19) United States
(12) Patent Application Publication
(10) Pub. No.: US 2014/0242367 A1
(43) Pub. Date: Aug. 28, 2014

(54) BARRIER FILM AND METHODS OF MAKING SAME

(71) Applicant: AU OPTRONICS CORPORATION, Hsinchu (TW)

(72) Inventors: Ching-Hsiang Chang, Hsinchu (TW); Yen-Cheng Kung, Hsinchu (TW); Po-Ching Hsu, Hsinchu (TW); Chung-Chih Wu, Hsinchu (TW); Shiuan-Iou Lin, Hsinchu (TW); Tai-Hsiang Huang, Hsinchu (TW); Jen-Kuei Lu, Hsinchu (TW); Norio Sugiura, Hsinchu (TW)

(73) Assignee: AU OPTRONICS CORPORATION, Hsinchu (TW)

(21) Appl. No.: 13/776,096

(22) Filed: Feb. 25, 2013

(51) Int. Cl. H01L 23/00; H01L 21/02

(52) U.S. Cl. CPC H01L 23/564; H01L 21/02216
USPC 428/220; 427/577; 252/62.3 Q

(57) ABSTRACT

A barrier film for blocking moisture and oxygen transmission includes a single layer grown from a precursor of organic silicide by a chemical vapor deposition, having at least silicon (Si) atoms, oxygen (O) atoms and carbon (C) atoms with atomic ratios of C/Si in a range of about 0.1-0.5, and O/Si in a range of about 2.0-2.5. The Si and O atoms form four bonding structures: Si(—O)4, Si(—O)3, Si(—O)2, and Si(—O)1, in the single layer. In the total amount of the four bonding structures being 100%, the bonding structures of Si(—O)4, Si(—O)3, Si(—O)2, and Si(—O)1 are in ranges of about 50%-99.9%, 0.01%-50%, 0%-10%, and 0%-10%, respectively.

### FIELD OF THE INVENTION

The disclosure relates generally to a barrier film, and more particularly to a single layered barrier film grown from a precursor of organic silicide by chemical vapor deposition (CVD), and methods of making the same.

### BACKGROUND OF THE INVENTION

In the field of flexible electronics and flexible displays, quality of protective barrier layer(s) and dielectric layer(s) of a thin film transistor (TFT) component or a display pixel structure directly affects its performance. Thus, how to form oxygen blocking and water repellent, protective layer and dielectric layer with high quality at low temperature is crucial for production of the flexible electronics and the flexible displays.

Conventionally, SiO₂ has strong capability of blocking electrons from transferring through, and blocking oxygen (gas) and moisture (water) from transmitting through as well. Formation of a protective, barrier film of SiO₂ usually requires at a high temperature. However, when grown on a flexible plastic substrate, flexing of the substrate may occur because the temperature resistance of the substrate durable to the high temperature is not high enough, which results in defects, even cracks, generated in the SiO₂ film. Accordingly, electrons can easily pass through passages formed by the defects and/or cracks, and the protection of the film from transmitting oxygen and moisture is therefore greatly compromised, which makes the control of current leaking very difficult. As a result, the reliability of electronic components is substantially reduced due to the defects of the protective film.

A protective barrier layer of a purely organic material can be grown at low temperature, and is flexible as well, but its material characteristics cannot meet the requirements of moisture/water and oxygen barrier. Usually, in order to avoid deteriorating the moisture and oxygen blocking properties due to defeats of a single layer, while to be flexible, a moisture and oxygen barrier film is formed by alternatively stacking a plurality of organic layers and inorganic layers in a staggered or gradient configuration. However, for such a multiple organic-inorganic interleaved multilayer structure, the etching process in fabricating an array of an electronic device is very complex, and thus, the multilayer structure can not easily be integrated into the TFT structures of the array.

Therefore, a heretofore unaddressed need exists in the art to address the aforementioned deficiencies and inadequacies.

### SUMMARY OF THE INVENTION

In one aspect, the invention relates to a barrier film for blocking moisture and oxygen transmission. The barrier film includes a single layer, and grown from a precursor of organic silicide by chemical vapor deposition (CVD). The single layer contains at least silicon (Si) atoms, oxygen (O) atoms and carbon (C) atoms with atomic ratios of C/Si in a range of about 0.1-0.5, and O/Si in a range of about 2.0-2.5. The Si and O atoms form four bonding structures: Si(—O)4, Si(—O)3, Si(—O)2, and Si(—O)1, in the single layer. In the total amount of the four bonding structures being 100%, the first bonding structure of Si(—O)4 is in a range of about 50%-99.9%, the second bonding structure of Si(—O)3 is in a range of about 0.01%-50%, the third bonding structure of Si(—O)2 is in a range of about 0%-10%, and the fourth bonding structure of Si(—O)1 is in a range of about 0%-10%, respectively.

Compositions of the single layer are uniformly formed therein.

Thickness of the single layer is about 10-500 nm.

In one embodiment, in use, the single layer is directly deposited onto a surface of a substrate, alternately deposited between an electrode layer, insulating layer and semiconductor layer of an electronic device, or deposited to form a top layer of a overall structure of an electronic device.

In one embodiment, the single layer is formed by a plasma-enhanced chemical vapor deposition (PECVD), or an inductively coupled plasma chemical vapor deposition (ICP-CVD).

In one embodiment, the single layer is deposited onto a first surface of a substrate. During the deposition, a bias voltage is applied to an opposite, second surface of the substrate.

In one embodiment, the organic silicide comprises hexamethyldisiloxane (HMDSO), hexamethyldisilazane (HMDSN), tetraethoxysilane (TEOS), Si(CH3)3Cl, or the likes.

In one embodiment, the barrier film is characterized with a water vapor transmission rate (WVTR) that is less than about 5×10⁻⁴ g/m² per day.

In one aspect, the invention relates to a method of fabricating a barrier film for blocking moisture and oxygen transmission by a chemical vapor deposition. In one embodiment, the method includes placing a substrate into a vacuum chamber; injecting reactants of organic silicide and oxygen (O₂) into the vacuum chamber; generating a plasma from the injected reactants; and depositing the plasma onto the substrate to form the barrier film, where a reactant ratio of [organic silicide/(O₂+ organic silicide)] is in a range of about 0.05-0.10, and a working pressure of the vacuum chamber is in a range of about 10-80 mTorr.

In one embodiment, the step of injecting the reactants includes transiting the organic silicide from a liquid phase to a gas phase by heating; and injecting the gaseous organic silicide into the vacuum chamber.

In one embodiment, the organic silicide comprises hexamethyldisiloxane (HMDSO), hexamethyldisilazane (HMDSN), tetraethoxysilane (TEOS), Si(CH3)3Cl, or the likes.

In one embodiment, the chemical vapor deposition is a PECVD.

In another embodiment, the chemical vapor deposition is an ICP-CVD. The step of generating the plasma comprises generating an inductively-coupled electrical field in the vacuum chamber, such that the plasma is generated by an interaction of the injected gas and the inductively-coupled electrical field, where the inductively-coupled electrical field is generated by an induction coil.

In one embodiment, the method further includes applying a bias voltage on the substrate.

In one embodiment, the substrate is formed of poly(methyl methacrylate) (PMMA), polyethylene terephthalate (PET), polyethersulphone (PES), polycarbonate (PC), copolyester thermoplastic elastomer (COP), polysulfone, phenolic resin, epoxy resin, polyester, polyetherester, polyetheramide, cellulose acetate, aliphatic polyurethane, polyacrylonitrile, polytetrafluoroethylenes, polyvinylidene fluorides, polytetrafluoroethylenes, high-density polyethylene (HDPE), poly(methyl a-methacrylates), or a combination thereof.

In yet another aspect, the invention relates to a method of fabricating a barrier film for blocking moisture and oxygen transmission by a chemical vapor deposition. In one embodiment, the method includes injecting reactants of organic silicide and oxygen (O₂) into a vacuum chamber; generating a plasma from the injected reactants; and depositing the plasma onto a substrate placed in the vacuum chamber to form the barrier film comprising at least silicon (Si) atoms, oxygen (O) atoms and carbon (C) atoms with atomic ratios of C/Si in a range of about 0.1-0.5, and O/Si in a range of about 2.0-2.5, where the Si and O atoms form four bonding structures: Si(—O)4, Si(—O)3, Si(—O)2, and Si(—O)1, in the barrier film, and in the total amount of the four bonding structures being 100%, the first bonding structure of Si(—O)4 is in a range of about 50%-99.9%, the second bonding structure of Si(—O)3 is in a range of about 0.01%-50%, the third bonding structure of Si(—O)2 is in a range of about 0%-10%, and the fourth bonding structure of Si(—O)1 is in a range of about 0%-10%, respectively.

In one embodiment, the organic silicide comprises HMDSO, and a reactant ratio of [organic silicide/(O₂+ organic silicide)] is in a range of about 0.05-0.10, and a working pressure of the vacuum chamber is in a range of about 10-80 mTorr.

In one embodiment, the chemical vapor deposition is a PECVD.

In another embodiment, the chemical vapor deposition is an ICP-CVD. The step of generating the plasma comprises generating an inductively-coupled electrical field in the vacuum chamber, such that the plasma is generated by an interaction of the injected gas and the inductively-coupled electrical field.

In one embodiment, the method further includes applying a bias voltage on the substrate.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1 shows schematically a system of inductively-coupled plasma chemical vapor deposition (ICP-CVD) for making a barrier film according to one embodiment of the present invention;

FIG. 2 shows relationships between Si/C/O atomic ratio of a barrier film and the reactant ratio of HMDSO/(O₂+ HMDSO) injected into the chamber to form the barrier film according to one embodiment of the present invention, (A) ICP power=100 W, and (B) ICP power=150 W;

FIG. 3 shows relationships between Si/C/O atomic ratio of a barrier film and the ICP power applied to the induction coil of the chamber to form the barrier film according to one embodiment of the present invention, (A) HMDSO/O₂=2/48 sccm, (B) HMDSO/O₂=4/46 sccm, and (C) HMDSO/O₂=6/44 sccm;

FIG. 4 shows XPS spectra showing types of bonding structures of a barrier film formed according to one embodiment of the present invention, (A) HMDSO/O₂=2/48 sccm and ICP power=100 W, and (B) HMDSO/O₂=2/48 sccm and ICP power=150 W;

FIG. 5 shows XPS spectra showing types of bonding structures of a barrier film formed according to another embodiment of the present invention, (A) HMDSO/O₂=4/46 seem and ICP power=100 W, and (B) HMDSO/O₂=4/46 seem and ICP power=150 W;

FIG. 6 shows XPS spectra showing types of bonding structures of a barrier film formed according to yet another embodiment of the present invention, (A) HMDSO/O₂=6/44 sccm and ICP power=100 W, and (B) HMDSO/O₂=6/44 sccm and ICP power=150 W;

FIG. 7 shows relationships between proportions of Si 2p peak of a barrier film and the reactant ratio of HMDSO/(O₂+ HMDSO) injected into the chamber to form the barrier film according to one embodiment of the present invention; and

FIGS. 8-13 respectively show a water vapor transmission rate (WVTR) of a barrier film formed according to different embodiments of the present invention.

### DETAILED DESCRIPTION OF THE INVENTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terms used in this specification generally have their ordinary meanings in the art, within the context of the invention, and in the specific context where each term is used. Certain terms that are used to describe the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top”, may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper”, depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about”, “substantially” or “approximately” shall generally mean within 20 percent, preferably within 10 percent, and more preferably within 5 percent of a given value or range. Numerical quantities given herein are approximate, meaning that the term “around”, “about”, “substantially” or “approximately” can be inferred if not expressly stated.

As used herein, if any, the term “X-ray photoelectron spectroscopy” or its abbreviation “XPS” refers to a quantitative spectroscopic technique that measures the elemental composition, empirical formula, chemical state and electronic state of the elements that exist within a material. XPS spectra are obtained by irradiating a material with a beam of X-rays while simultaneously measuring the kinetic energy and number of electrons that escape from the material being analyzed.

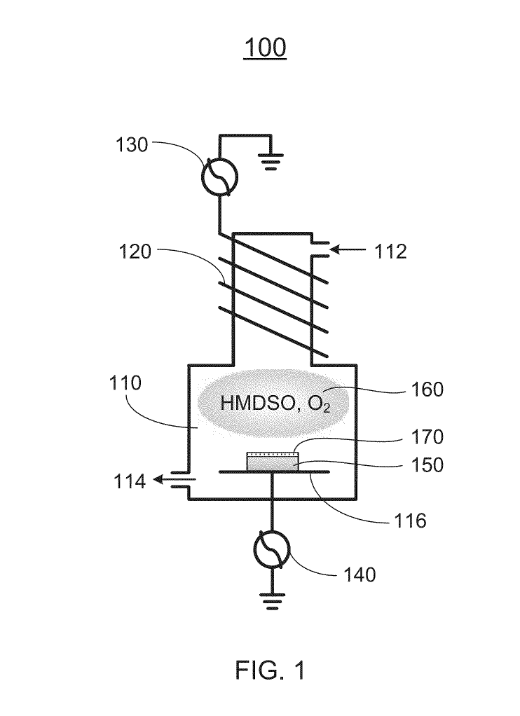

The description will be made as to the embodiments of the present invention in conjunction with the accompanying drawings in FIGS. 1-13. In accordance with the purposes of this invention, as embodied and broadly described herein, this invention, in one aspect, relates to a single layered barrier film for blocking moisture and oxygen transmission and methods of making the same. The barrier film, among other things, has extremely high barrier, optical and electrical properties.

In one embodiment, the single layered barrier film is grown from a precursor of organic silicide by a modified chemical vapor deposition (CVD) at low temperature, and has a thickness of about 10-500 nm. The organic silicide includes hexamethyldisiloxane (HMDSO), hexamethyldisilazane (HMDSN), tetraethoxysilane (TEOS), Si(CH3)3Cl, or the likes. According to the invention, the barrier film is formed of hybrid SiOx in a single layer and contains at least silicon (Si) atoms, oxygen (O) atoms and carbon (C) atoms with atomic ratios of C/Si in a range of about 0.1-0.5, and O/Si in a range of about 2.0-2.5. The chemical vapor deposition can be a plasma-enhanced chemical vapor deposition (PECVD), or an inductively coupled plasma chemical vapor deposition (ICP-CVD).

The atomic and bonding compositions of the single layered barrier film are obtained by X-ray photoelectron spectroscopy (XPS) analysis. These compositions are uniformly formed in the barrier film. According to the invention, that the Si and O atoms form four bonding structures: Si(—O)4, Si(—O)3, Si(—O)2 and Si(—O)1. In the total amount of the four bonding structures being 100%, the first bonding structure of Si(—O)4 is in a range of about 50%-99.9%, the second bonding structure of Si(—O)3 is in a range of about 0.01%-50%, the third bonding structure of Si(—O)2 is in a range of about 0%-10%, and the fourth bonding structure of Si(—O)1 is in a range of about 0%-10%, respectively, in the single layered barrier film.

The barrier properties of the single layered barrier film can be characterized with a water vapor transmission rate (WVTR), which is extremely low, for example, less than about 5×10⁻⁴ g/m² per day, according to one embodiment of the invention.

Since the single layered barrier film has extremely high barrier, optical and electrical properties, it can find widespread applications in semiconductor component, electronic devices, flexible displays, and so on. In use, the single layered barrier film can directly be deposited onto a surface of a substrate. In addition, the single layered barrier film may alternately be deposited between an electrode layer, insulating layer and semiconductor layer of an electronic device. Further, the single layered barrier film may be deposited to form a top layer of an overall structure of an electronic device for blocking moisture and oxygen transmission through the barrier film.

Referring to FIG. 1, an ICP-CVD system 100 for making a single layered barrier film 170 is schematically shown according to one embodiment of the present invention. The ICP-CVD system 100 has a chamber 110, an induction coil 120 surrounding at least a portion of chamber 110 for generating an inductively-coupled electrical field in the chamber 110, and an ICP power source 130 disposed outside the chamber 110 for providing power supply to the induction coil 120. The chamber 110 has an inlet 112 for injecting reactant gases and an outlet 114 for removing exhausted gases. The chamber 110 is capable of accommodating the injection of one or more types of gases, and is provided with a support stand 116 to place a substrate 150. Preferably, the chamber 110 is a vacuum chamber. A DC bias voltage supply 140 is electrically connected to the substrate 150, the induction coil 120 and the DC bias voltage supply 140 are both disposed outside the chamber 110, and are utilized to generate plasma and provide bias voltage, respectively. The substrates can be a flexible plastic film formed of polyethylene naphthalate (PEN), polyimide (PI), cyclic olefin copolymer (COC), poly(methyl methacrylate) (PMMA), polyethylene terephthalate (PET), polyethersulphone (PES), polycarbonate (PC), copolyester thermoplastic elastomer (COP), polysulfone, phenolic resin, epoxy resin, polyester, polyetherester, polyetheramide, cellulose acetate, aliphatic polyurethane, polyacrylonitrile, polytetrafluoroethylenes, polyvinylidene fluorides, polytetrafluoroethylenes, high-density polyethylene (HDPE), poly(methyl a-methacrylates), or a combination thereof. The thickness of the substrate is in a range of about 10-500 μm.

When the reactant gases of organic silicide, such as HMDSO, and oxygen (O₂) are injected into the vacuum chamber 110, it is turned into high density plasma through the action of the electrical field generated by the inductive coupling of the induction coil 120, thus the plasma diffused into the substrate 150 produces the effects of absorption, reaction, and migration. Accordingly, the material 160 of the generated plasma is deposited on the substrate 150 to form the single layered barrier film 170. During the deposition, the bias voltage supplied from the DC bias voltage source 140 is applied to the substrate 150, which enhances the fabricating process of the barrier film 170. The material 160 deposited on the substrate 150 under influence of the bias voltage applied by the DC bias voltage supply 140 on the substrate 150 makes the heat generated by the bombardment of substrate 150 by the ions transmit smoothly to the silicon atoms on the surface of the material, such that the silicon atoms may have sufficient diffusion energy to raise the degree of crystallization of the material and produce the single layered barrier film 170 at low substrate temperature.

According to the invention, the method of fabricating the barrier film 170 with the ICP-CVD system 100 includes the following steps: at first, the substrate 150 is placed into the chamber 110. The reactants of organic silicide and oxygen (O₂) gases are then injected into the chamber 110. The organic silicide includes HMDSO, HMDSN, TEOS, Si(CH3)3Cl, or the likes. In one embodiment, the organic silicide such as HMDSO is first transitioned from a liquid phase to a gas phase by heating; and then the gaseous HMDSO is injected into the vacuum chamber 110. In one embodiment, a reactant ratio of [organic silicide/(O₂+ organic silicide)] is in a range of about 0.05-0.10, and a working pressure of the vacuum chamber 110 is in a range of about 10-80 mTorr.

Then, plasma is generated from the injected reactants of HMDSO and O₂, by an interaction of the injected reactants and the inductively-coupled electrical field generated by the induction coil 120 in the vacuum chamber 110.

The generated plasma is deposited onto the substrate 150 to form the barrier film 170. During deposition, a bias voltage supplied from the DC bias voltage source 140 is applied onto the substrate 150.

In one embodiment, the barrier film is formed of a compound having at least silicon (Si) atoms, oxygen (O) atoms and carbon (C) atoms with atomic ratios of C/Si in a range of about 0.1-0.5, and O/Si in a range of about 2.0-2.5. The Si and O atoms form four bonding structures: Si(—O)4, Si(—O)3, Si(—O)2, and Si(—O)1, in the barrier film, where in the total amount of the four bonding structures being 100%, the first bonding structure of Si(—O)4 is in a range of about 50%-99.9%, the second bonding structure of Si(—O)3 is in a range of about 0.01%-50%, the third bonding structure of Si(—O)2 is in a range of about 0%-10%, and the fourth bonding structure of Si(—O)1 is in a range of about 0%-10%, respectively.

Without intent to limit the scope of the invention, exemplary barrier films according to various embodiments of the present invention and their related characteristics are given below.

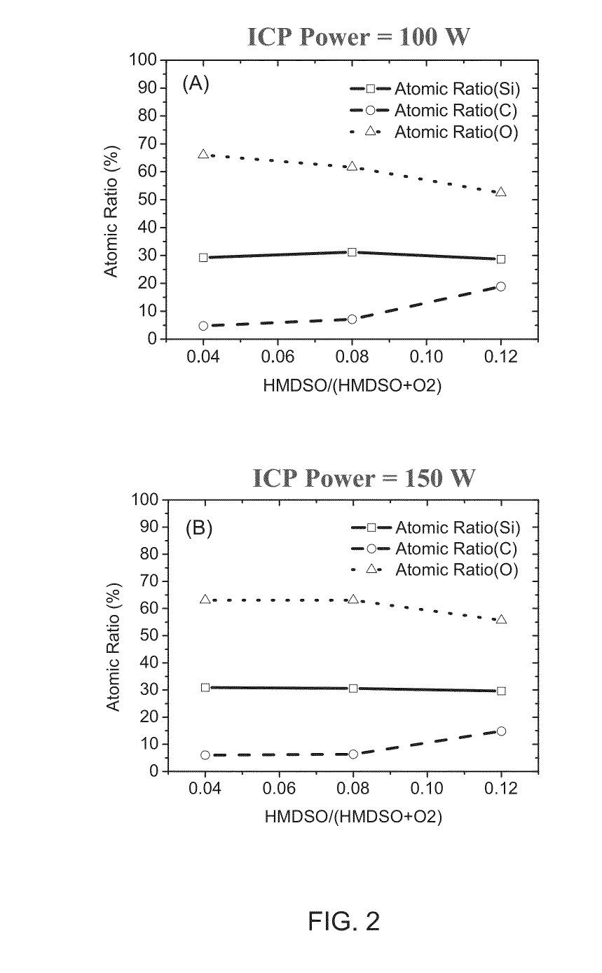

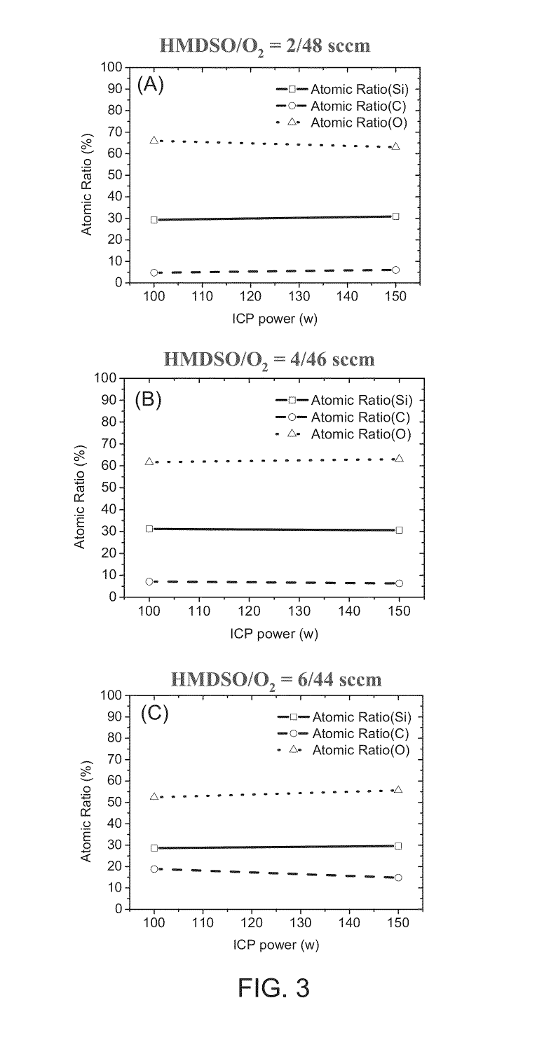

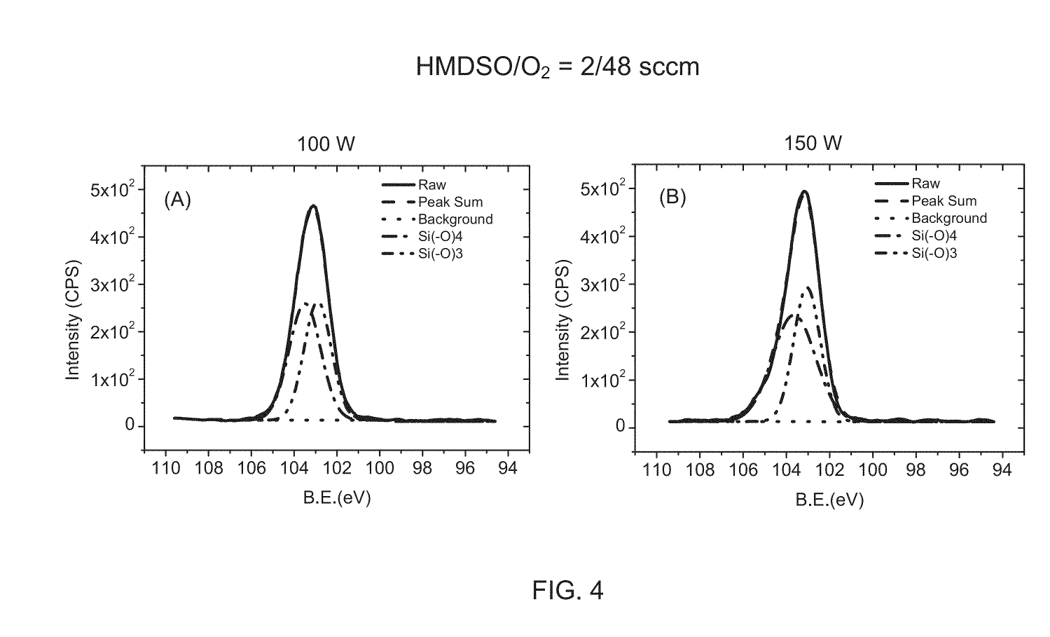

FIG. 2 shows relationships between Si/C/O atomic ratio of a barrier film and the reactant ratio of HMDSO/(O₂+ HMDSO) injected into the chamber to form the barrier film, while FIG. 3 shows relationships between Si/C/O atomic ratio of a barrier film and the ICP power applied to the induction coil of the chamber to form the barrier film. Accordingly to the invention, under the same ICP power, different reactant ratios of HMDSO/(O₂+ HMDSO) injected into the chamber result in the barrier film formed to have different atomic ratios of Si, C and O atoms, i.e., different compositions. For example, as shown in FIG. 2(A), under the ICP power=100 W, for HMDSO/(O₂+ HMDSO)=0.08, the barrier film is formed to have about 62% of oxygen atoms, about 31% of silicon atoms and about 7% of carbon atoms. The barrier film has the WVTR less than about 5×10⁻⁴ g/m² per day. Similarly, under the same reactant ratios of HMDSO/(O₂+ HMDSO) injected into the chamber, different ICP powers applied to the induction coil of the chamber result in the barrier film formed to have different compositions, as shown in FIG. 3. Comparatively, the atomic ratios of Si, C and O atoms of a barrier film are more sensitive to the reactant ratios of HMDSO/(O₂+ HMDSO) injected into the chamber, as shown in FIG. 2, rather than the ICP powers applied to the induction coil of the chamber, as shown in FIG. 3. However, as characterized in the XPS spectra shown in FIGS. 4-6, the proportion of the bonding structures Si(—O)4 and Si(—O)3 of the barrier film are more sensitive to the ICP power.

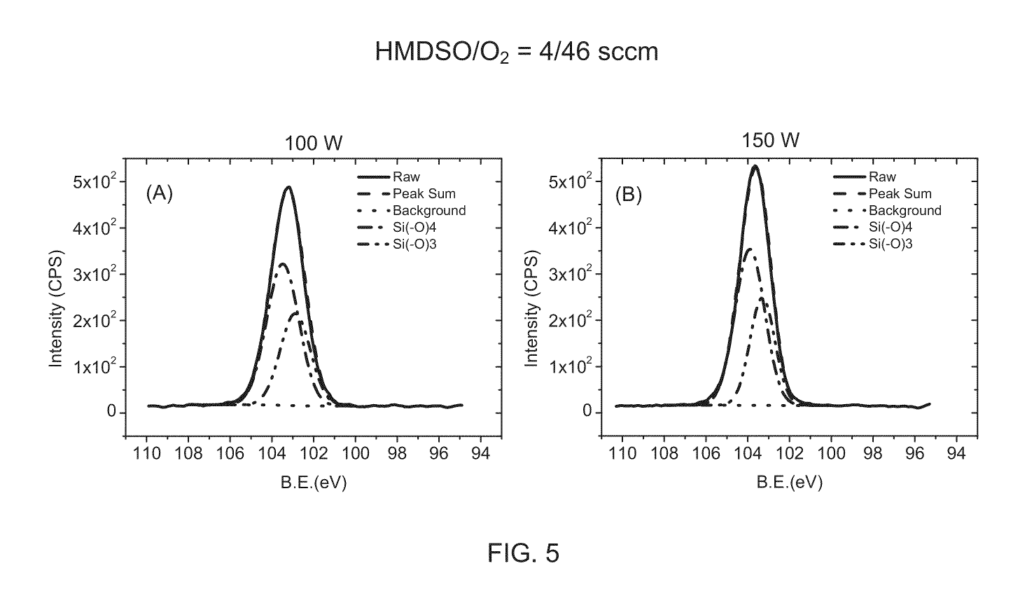

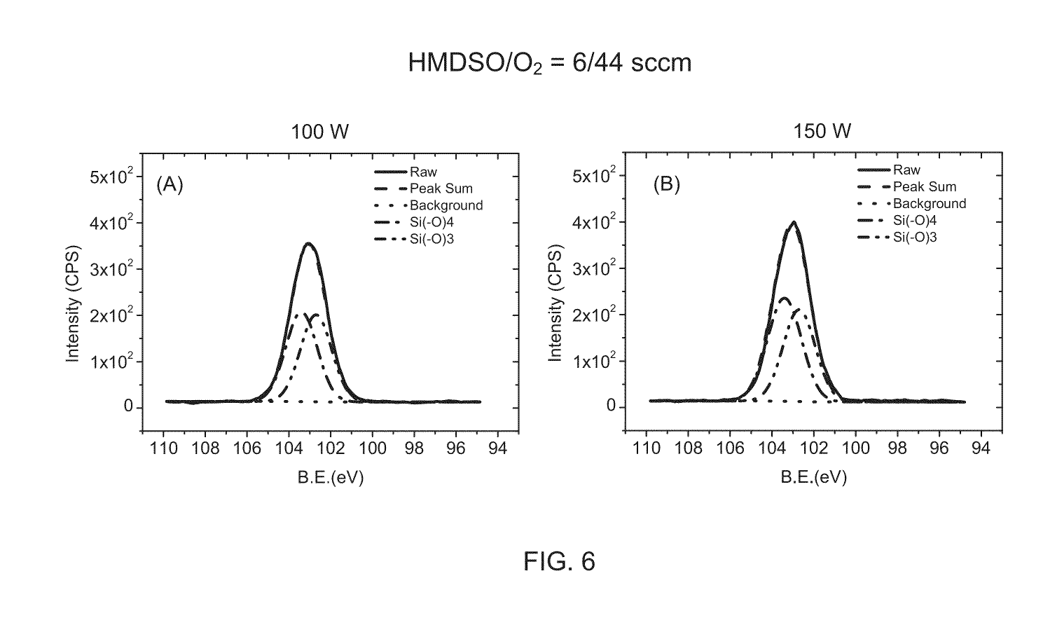

FIGS. 4-6 are XPS spectra of different barrier films formed in different conditions, which identify types of bonding structures of these barrier films, respectively. For the barrier films shown in FIGS. 4-6, HMDSO/O₂=2/48 sccm, HMDSO/O₂=4/46 HMDSO/O₂=6/44 sccm, respectively. For the exemplary barrier films shown in each of FIGS. 4-6, (A) ICP power=100 W, and (B) ICP power=150 W. Generally, Si(—O)4 is the most dense ideal bonding structure that is the key factor to improve the WVTR of a barrier film. As shown in FIG. 5, the intensities of Si(—O)4 and Si(—O)3 of the barrier film (HMDSO/O₂=4/46 sccm) are higher than that of Si(—O)4 and Si(—O)3 of the barrier films shown in FIGS. 4 and 6. Further, the proportion of Si(—O)4 is higher that of Si(—O)3 of the barrier film (HMDSO/O₂=4/46 sccm) shown in FIG. 5. Accordingly, the barrier film shown in FIG. 5 has the lower WVTR.

In the following exemplary embodiment, a single-layered barrier film was fabricated with the above-disclosed process in the ICP-CVD system under the following conditions/parameters:

HMDSO/O₂=4/46 sccm,

Chamber Pressure=40 mTorr,

ICP Power=150 W, and

Substrate Power=20 W.

The exemplary barrier film was formed on a PEN substrate and has a thickness of about 150 nm.

By the XPS analysis, the exemplary barrier film is characterized with:

C/Si=0.21, and

O/Si=2.06.

Si(—O)4=65%,

Si(—O)3=35%,

Si(—O)2=0%, and

Si(—O)1=0%.

As formed, the proportion of Si(—O)4 is higher that of Si(—O)3 in the exemplary barrier film. The exemplary barrier film was tested in terms of WVTR under the relative humidity of about 100% for about one day. The normalized WVTR is less than about 5×10⁻⁴ g/m² per day, which shows that the barrier film has an extremely high water repellent property.

In the exemplary barrier films characterized in FIGS. 4-6, there exist only bonding structures of Si(—O)4 and Si(—O)3. In other embodiments, in addition to the bonding structures of Si(—O)4 and Si(—O)3, the bonding structures of Si(—O)2 and Si(—O)1 may also exist in a barrier film fabricated under different conditions.

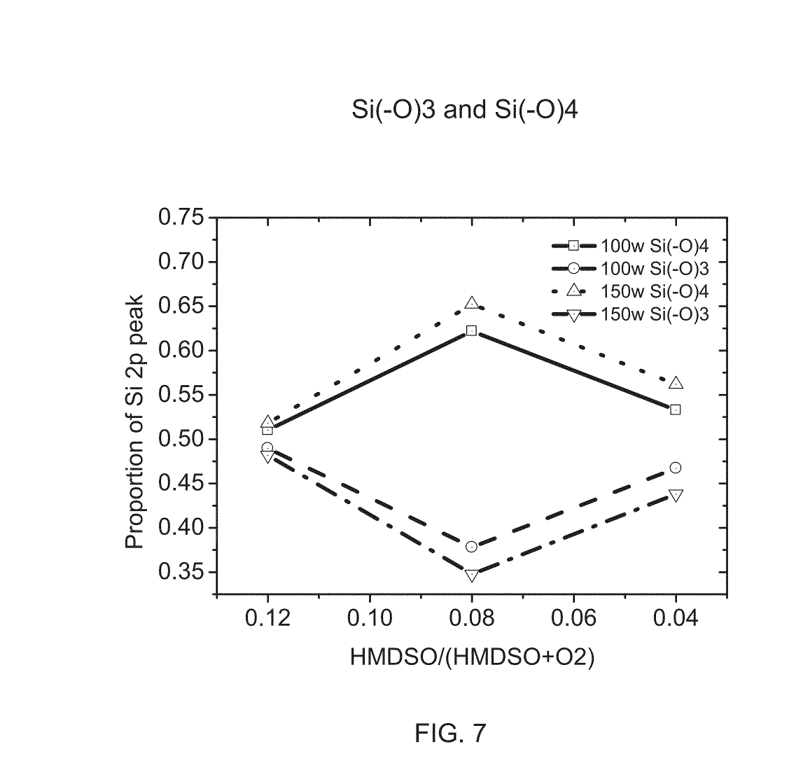

The XPS data comparison of barrier films under different fabrication conditions is shown in FIG. 7, in terms of the relationships between proportions of Si 2p peak of the barrier films and the reactant ratios of HMDSO/(O₂+ HMDSO) injected into the chamber to form the barrier films. It is clearly shown that the barrier films have different proportions of the bonding structures Si(—O)4 and Si(—O)3, when the ICP powers are different. For example, the proportion of the bonding structure Si(—O)4 in the barrier film fabricated under the ICP power=150 W is higher than that under the ICP power=100 W. Thus, the barrier film fabricated under the ICP power=150 W has a better WVTR. In addition, different reactant ratios of HMDSO/(O₂+ HMDSO) also result in different proportions of the bonding structures Si(—O)4 and Si(—O)3 in the barrier films. For the exemplary example shown in FIG. 7, when HMDSO/(O₂+ HMDSO)=0.08 (4/46), the proportion of the bonding structure Si(—O)4 in the barrier film reaches to its maximal value. Accordingly, the barrier film fabricated under HMDSO/(O₂+ HMDSO)=0.08 has the best WVTR.

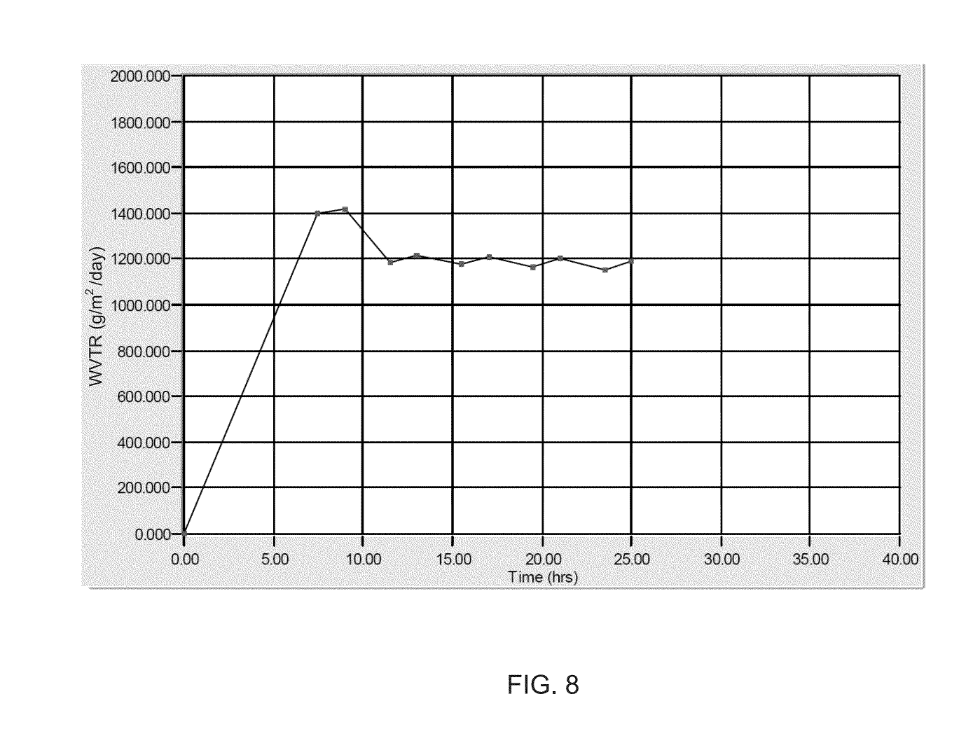

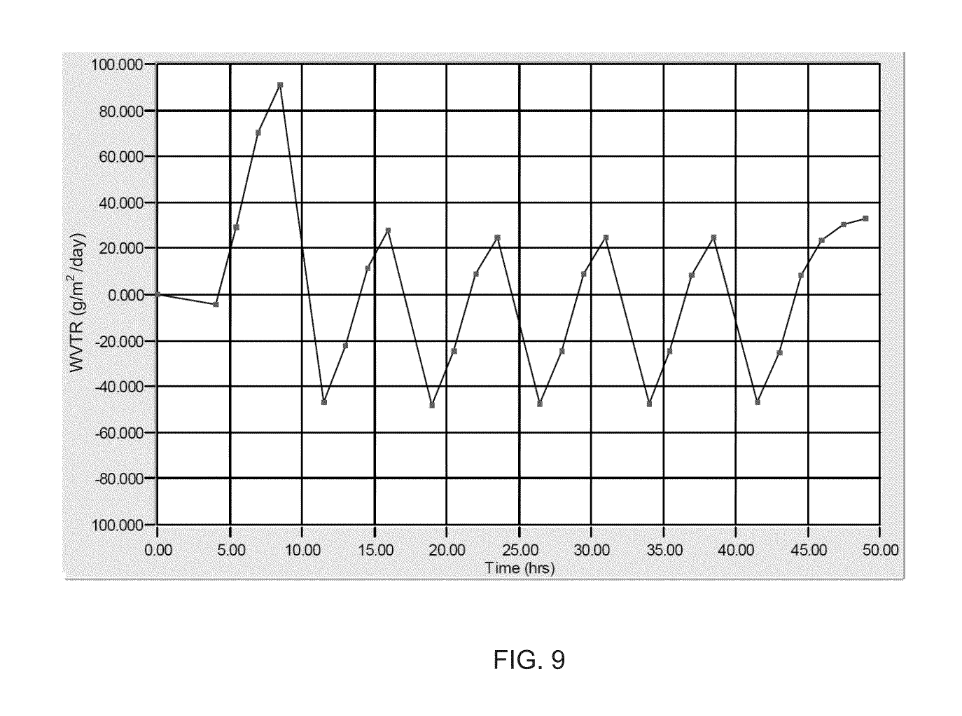

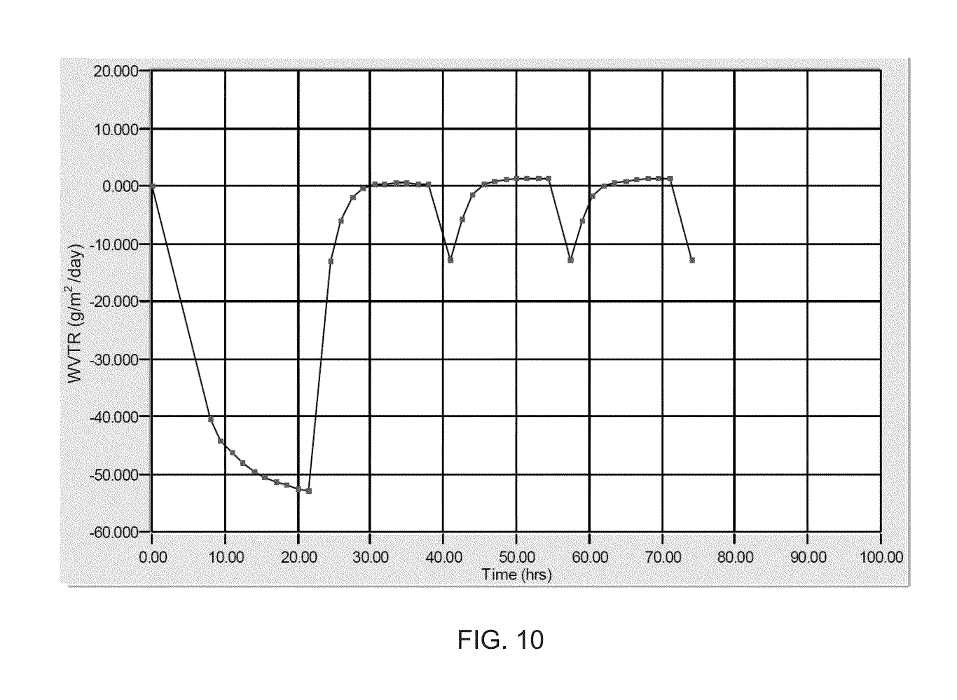

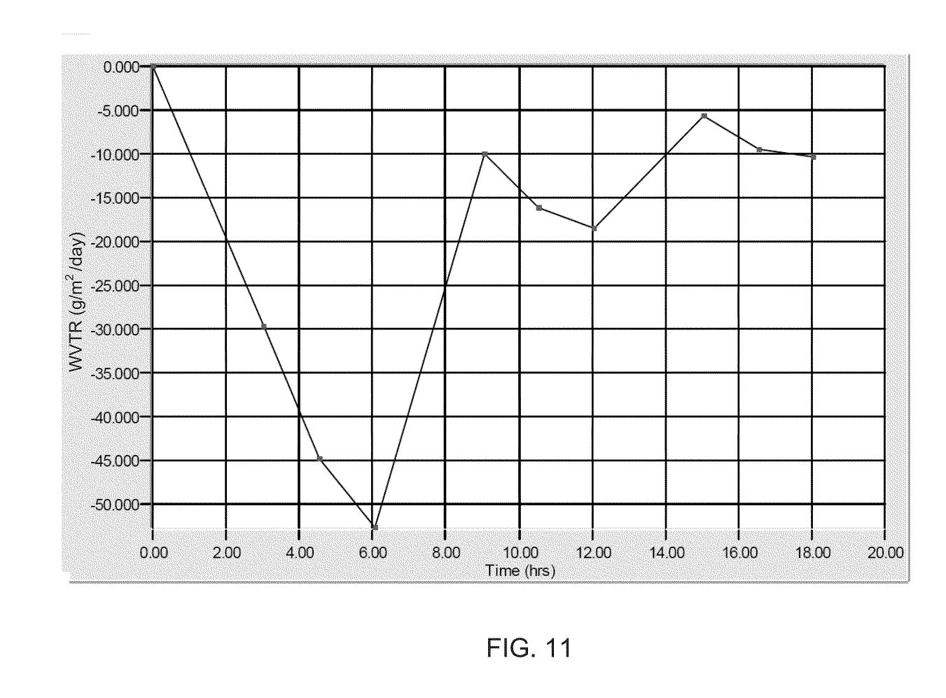

FIGS. 8-13 respectively show a WVTR of barrier films fabricated according to different embodiments of the present invention. Referring to Table 1, the barrier films were fabricated in the same substrate power (i.e., 20 W), and different HMDSO/O₂, and different ICP powers, and have a film thickness of about 100 nm (FIG. 9) or 150 nm (FIGS. 8 and 10-13). These barrier films were tested for about 25 hrs at the same ambient temperature of about 23° C., and different relative humidity of about 44.7% (FIG. 8), 55.4% (FIG. 10) or 100% (FIGS. 9 and 11-13). Accordingly, the WVTR are also different for different barrier films, where the WVTR of the barrier films (HMDSO/O₂=2/46 sccm) characterized in FIGS. 10 and 11 is lower than that of others characterized in FIGS. 8, 9, 12 and 13.

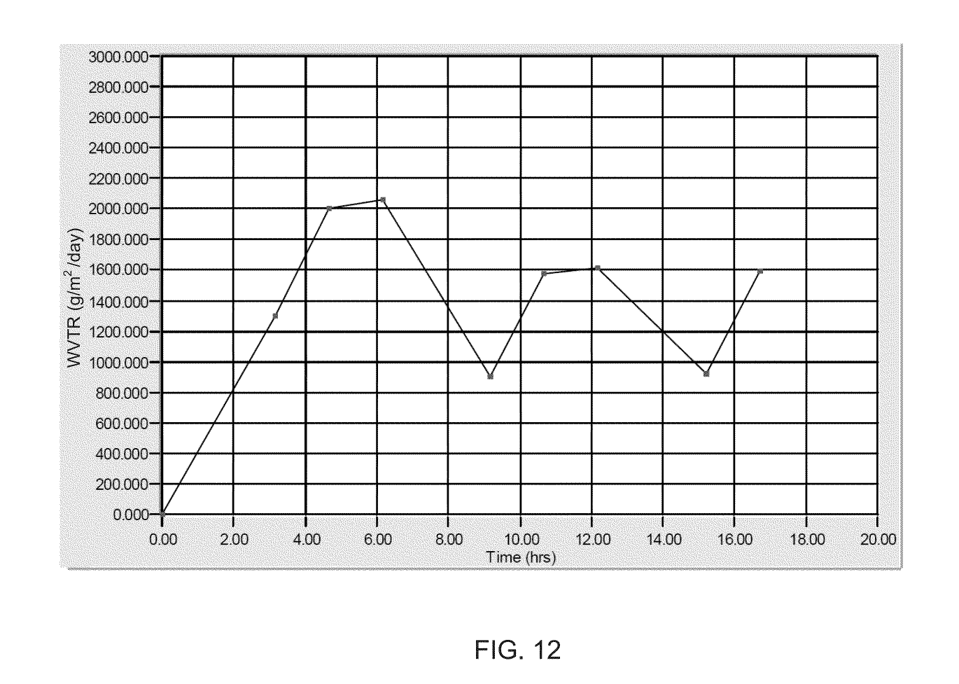

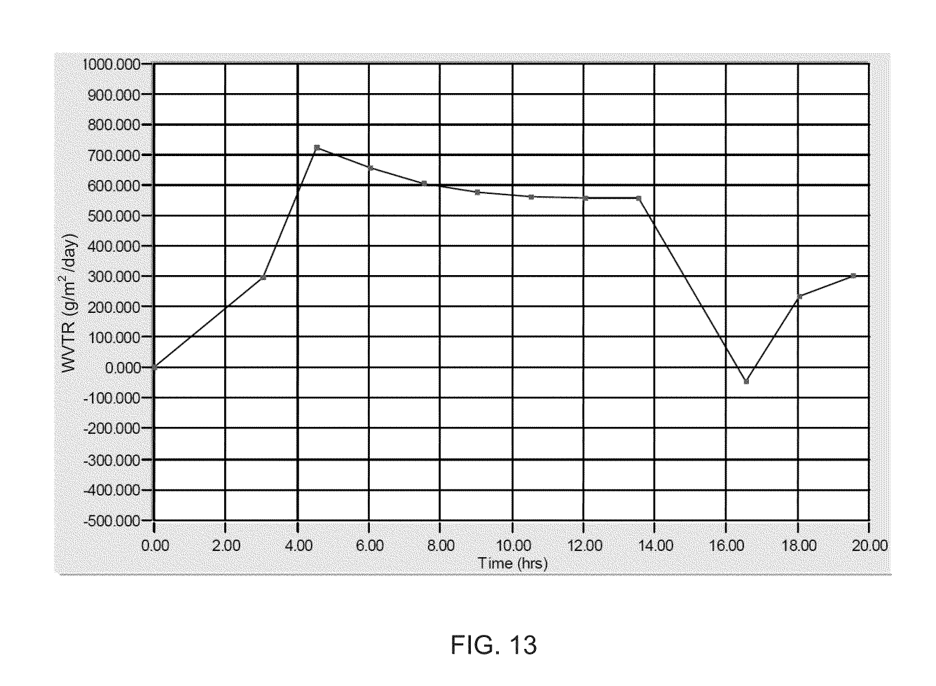

TABLE 1
WVTR of barrier films fabricated in different conditions and
tested in different environments.

| | | | Sub- | Film | | |
|---|---|---|---|---|---|---|
| | HMDSO/ | ICP | strate | Thick- | Relative | WVTR |
| Barrier | O₂ | Power | Power | ness | Humidity | (mg/m²/ |
| Film | (sccm) | (W) | (W) | (nm) | (%) | day) |
| FIG. 8 | 2/48 | 100 | 20 | 150 | 44.7 | 1187.495 |
| FIG. 9 | 2/48 | 150 | 20 | 100 | 100 | 33.089 |
| FIG. 10 | 2/46 | 100 | 20 | 150 | 55.4 | −12.871 |
| FIG. 11 | 2/46 | 150 | 20 | 150 | 100 | −10.286 |
| FIG. 12 | 2/44 | 100 | 20 | 150 | 100 | 1598.712 |
| FIG. 13 | 2/44 | 150 | 20 | 150 | 100 | 302.751 |

In sum, the present invention recites, among other things, a single layered barrier film for blocking moisture and oxygen transmission and methods of making the same. The barrier film has a single layer with a thickness of about 10-500 nm, grown from a precursor of organic silicide by a chemical vapor deposition, and has at least silicon (Si) atoms, oxygen (O) atoms and carbon (C) atoms with atomic ratios of C/Si in a range of about 0.1-0.5, and O/Si in a range of about 2.0-2.5. The Si and O atoms form four bonding structures: Si(—O)4, Si(—O)3, Si(—O)2, and Si(—O)1, in the single layer. The barrier film has an extremely high water repellent property.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

1. A barrier film for blocking moisture and oxygen transmission, comprising:
a single layer grown from a precursor of organic silicide by chemical vapor deposition (CVD), comprising at least silicon (Si) atoms, oxygen (O) atoms and carbon (C) atoms with atomic ratios of C/Si in a range of about 0.1-0.5, and O/Si in a range of about 2.0-2.5, wherein the Si and O atoms form four bonding structures: Si(—O)4, Si(—O)3, Si(—O)2, and Si(—O)1, in the single layer, and wherein in the total amount of the four bonding structures being 100%, the first bonding structure of Si(—O)4 is in a range of about 50%-99.9%, the second bonding structure of Si(—O)3 is in a range of about 0.01%-50%, the third bonding structure of Si(—O)2 is in a range of about 0%-10%, and the fourth bonding structure of Si(—O)1 is in a range of about 0%-10%, respectively.

2. The barrier film of claim 1, wherein compositions of the single layer are uniformly formed therein.

3. The barrier film of claim 1, wherein thickness of the single layer is about 10-500 nm.

4. The barrier film of claim 1, wherein in use, the single layer is directly deposited onto a surface of a substrate, alternately deposited between an electrode layer, insulating layer and semiconductor layer of an electronic device, or deposited to form a top layer of a overall structure of an electronic device.

5. The barrier film of claim 1, being characterized with a water vapor transmission rate (WVTR) that is less than about 5×10⁻⁴ g/m² per day.

6. A method of fabricating a barrier film for blocking moisture and oxygen transmission, comprising:
placing a substrate into a vacuum chamber for a chemical vapor deposition;
injecting reactants of organic silicide and oxygen (O₂) into the vacuum chamber;
generating a plasma from the injected reactants; and
depositing the plasma onto the substrate to form the barrier film,
wherein a reactant ratio of [organic silicide/(O₂+ organic silicide)] is in a range of about 0.05-0.10, and a working pressure of the vacuum chamber is in a range of about 10-80 mTorr.

7. The method of claim 6, wherein the organic silicide comprises hexamethyldisiloxane (HMDSO), hexamethyldisilazane (HMDSN), tetraethoxysilane (TEOS), Si(CH3)3Cl, or the likes.

8. The method of claim 7, wherein the step of injecting the reactants comprises:
transiting the organic silicide from a liquid phase to a gas phase by heating; and
injecting the gaseous organic silicide into the vacuum chamber.

9. The method of claim 6, wherein the chemical vapor deposition is a plasma-enhanced chemical vapor deposition (PECVD) or an inductively-coupled plasma chemical vapor deposition (ICP-CVD).

10. The method of claim 9, wherein the step of generating the plasma comprises generating an inductively-coupled electrical field in the vacuum chamber, such that the plasma is generated by an interaction of the injected gas and the inductively-coupled electrical field.

11. The method of claim 10, wherein the inductively-coupled electrical field is generated by an induction coil.

12. The method of claim 6, further comprising applying a bias voltage on the substrate.

13. The method of claim 6, wherein the substrate is formed of poly(methyl methacrylate) (PMMA), polyethylene terephthalate (PET), polyethersulphone (PES), polycarbonate (PC), copolyester thermoplastic elastomer (COP), polysulfone, phenolic resin, epoxy resin, polyester, polyetherester, polyetheramide, cellulose acetate, aliphatic polyurethane, polyacrylonitrile, polytetrafluoroethylenes, polyvinylidene fluorides, polytetrafluoroethylenes, high-density polyethylene (HDPE), poly(methyl α-methacrylates), or a combination thereof.

14. A method of fabricating a barrier film for blocking moisture and oxygen transmission, comprising:
injecting reactants of organic silicide and oxygen (O₂) into a vacuum chamber for a chemical vapor deposition;
generating a plasma from the injected reactants; and
depositing the plasma onto a substrate placed in the vacuum chamber to form the barrier film comprising at least silicon (Si) atoms, oxygen (O) atoms and carbon (C) atoms with atomic ratios of C/Si in a range of about 0.1-0.5, and O/Si in a range of about 2.0-2.5, wherein the Si and O atoms form four bonding structures: Si(—O)4, Si(—O)3, Si(—O)2, and Si(—O)1, in the barrier film, and wherein in the total amount of the four bonding structures being 100%, the first bonding structure of Si(—O)4 is in a range of about 50%-99.9%, the second bonding structure of Si(—O)3 is in a range of about 0.01%-50%, the third bonding structure of Si(—O)2 is in a range of about 0%-10%, and the fourth bonding structure of Si(—O)1 is in a range of about 0%-10%, respectively.

15. The method of claim 14, wherein the organic silicide comprises hexamethyldisiloxane (HMDSO), hexamethyldisilazane (HMDSN), tetraethoxysilane (TEOS), Si(CH3)3Cl, or the likes.

16. The method of claim 14, wherein a reactant ratio of [organic silicide/(O₂+ organic silicide)] is in a range of about 0.05-0.10, and a working pressure of the vacuum chamber is in a range of about 10-80 mTorr.

17. The method of claim 14, wherein the chemical vapor deposition is a plasma-enhanced chemical vapor deposition (PECVD) or an inductively-coupled plasma chemical vapor deposition (ICP-CVD).

18. The method of claim 17, wherein the step of generating the plasma comprises generating an inductively-coupled electrical field in the vacuum chamber, such that the plasma is generated by an interaction of the injected gas and the inductively-coupled electrical field.

19. The method of claim 14, further comprising applying a bias voltage on the substrate.
